(19) United States
(12) Patent Application Publication
(10) Pub. No.: US 2022/0336551 A1
(43) Pub. Date: Oct. 20, 2022

(54) DISPLAY DEVICE

(71) Applicant: Samsung Display Co., Ltd., Yongin-si (KR)

(72) Inventors: SOO-YOUNG JUNG, Hwaseong-si (KR); SUNGJUN KIM, Yongin-si (KR); CHUNGHYUK LEE, Hwaseong-si (KR); SUNG JAE JUNG, Yongin-si (KR)

(21) Appl. No.: 17/538,053

(22) Filed: Nov. 30, 2021

(30) Foreign Application Priority Data
Apr. 16, 2021 (KR) 10-2021-0049910

(51) Int. Cl. H01L 27/32; H01L 51/52

(52) U.S. Cl. CPC H01L 27/3246; H01L 51/5253

(57) ABSTRACT

A display device includes a substrate; a first electrode disposed on the substrate; and a pixel defining layer disposed on the substrate and which exposes the first electrode and includes a first region having a first height and a second region connected to the first region and having a second height higher than the first height.

This application claims priority to Korean Patent Application No. 10-2021-0049910, filed on Apr. 16, 2021, and all the benefits accruing therefrom under 35 U.S.C. § 119, the content of which in its entirety is herein incorporated by reference.

### BACKGROUND

### 1. Technical Field

Embodiments relate to a display device. More particularly, embodiments relate to a display device including an encapsulation layer.

### 2. Description of the Related Art

A display device may include a light emitting element to emit light. Examples of the light emitting element include an inorganic light emitting element and an organic light emitting element. The organic light emitting element is vulnerable to external stimuli. For example, when moisture permeates into the organic light emitting element, the organic light emitting element may not normally emit light. Accordingly, an encapsulation layer may be disposed to cover the organic light emitting element.

### SUMMARY

Embodiments may provide a display device including an encapsulation layer.

A display device according to an embodiment includes: a substrate; a first electrode disposed on the substrate; and a pixel defining layer disposed on the substrate and which exposes the first electrode and includes a first region having a first height and a second region connected to the first region and having a second height higher than the first height

In an embodiment, the display device may further include a light emitting layer disposed on the first electrode, a second electrode disposed on the light emitting layer and an encapsulation layer disposed on the second electrode.

In an embodiment, the encapsulation layer may include a first inorganic encapsulation layer disposed on the second electrode, an organic encapsulation layer disposed on the first inorganic encapsulation layer and a second inorganic encapsulation layer disposed on the organic encapsulation layer. The organic encapsulation layer may be formed by an inkjet printing process, and is spread from the second region to the first region by capillary pressure.

In an embodiment, the first height may be in a range of about 0.1 micrometers to about 1.9 micrometers.

In an embodiment, in a plan view, a region in which the pixel defining layer exposes the first electrode may have a circular shape.

In an embodiment, The first region is provided in plural, and the plurality of first regions may be disposed along a perimeter of the circular shape and may be spaced apart from each other.

In an embodiment, a length of a perimeter of a first one of the plurality of first regions may be different from a length of a perimeter of a second one of the plurality of first regions.

In an embodiment, the second region may be disposed adjacent to the first electrode, and a portion of the second region may be spaced apart from the first electrode by the first region.

In an embodiment, in a plan view, a region in which the pixel defining layer exposes the first electrode may have a polygonal shape.

In an embodiment, the plurality of first regions may be disposed along a perimeter of the polygonal shape and may be spaced apart from each other.

In an embodiment, the second region may be disposed adjacent to the first electrode, and a portion of the second region may be spaced apart from the first electrode by the first region

In an embodiment, the pixel defining layer may include: a lower pixel defining layer having the first height; and an upper pixel defining layer disposed on the lower pixel defining layer and having a third height that is a difference between the second height and the first height.

In an embodiment, the lower pixel defining layer and the upper pixel defining layer may include the same material.

In an embodiment, the lower pixel defining layer and the upper pixel defining layer may include different materials from each other.

In an embodiment, in a plan view, a length of a perimeter of a region in which the pixel defining layer exposes the first electrode may be longer than a length of a perimeter of the first region.

In an embodiment, in a plan view, the first region may have a circular shape.

In an embodiment, in a plan view, the first region may have a polygonal shape.

A display device according to embodiments of the present invention may include a first region and a second region provided adjacent to the pixel having different heights in the pixel defining layer. Accordingly, the ink applied to the second region may be easily spread by receiving the capillary pressure to the first region by the capillary pressure. Accordingly, the incorrectly applied ink may easily spread onto the pixel.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to embodiments.

FIGS. 2 and 3 are plan views illustrating a pixel included in the display device of FIG.

FIG. 4 is a cross-sectional view illustrating an embodiment of a cross-section taken along line I-I′ of FIG. 2.

FIG. 5 is a cross-sectional view illustrating an embodiment of a cross-section taken along line II-II′ of FIG. 2.

FIG. 6 is a cross-sectional view illustrating another embodiment of a cross-section taken along line I-I′ of FIG. 2.

FIG. 7 is a cross-sectional view illustrating another embodiment of a cross-section taken along line II-II′ of FIG. 2.

FIGS. 8, 9, 10, and 11 are plan views illustrating other embodiments of pixels included in the display device of FIG. 1.

FIG. 12 is a block view illustrating an electronic device according to an embodiment.

FIG. 13 is a diagram view an example in which the electronic device of FIG. 12 is implemented as a television.

FIG. 14 is a diagram illustrating an example in which the electronic device of FIG. 12 is implemented as a smartphone.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, display devices in accordance with embodiments will be explained in detail with reference to the accompanying drawings.

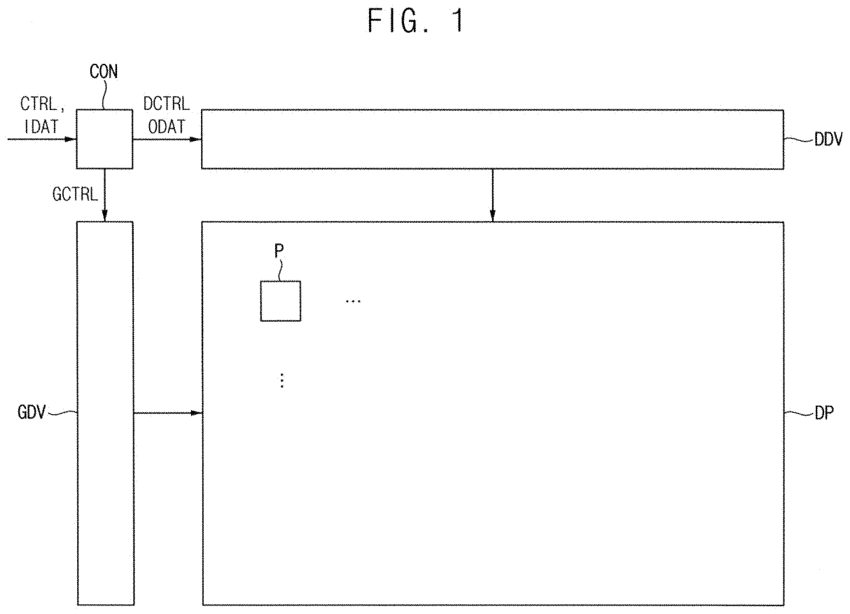

FIG. 1 is a block view illustrating a display device according to an embodiment.

Referring to FIG. 1, The display device may include a display panel DP, a data driver DDV, a gate driver GDV, and a timing controller CON.

The display device may display an image through the display panel DP. To this end, the display panel DP may include a plurality of pixels P. Each of the plurality of pixels P may include a light emitting element and element for driving the light emitting element (e.g., a transistor, a capacitor, etc.). Each of the pixels P may include a plurality of sub-pixels. The pixels P may be entirely disposed in the display panel DP. For example, the pixels P may be arranged in a matrix form in the display panel DP.

The pixels P may include a plurality of sub-pixels. For example, one pixel P may include one red sub-pixel, one blue sub-pixel, and one green sub-pixel. Alternatively, one pixel P may include one red sub-pixel, one blue sub-pixel, and two green sub-pixels. The plurality of sub-pixels may be arranged in a matrix form, a PENTILE™ form, an S-stripe form, or the like.

In embodiments, the display panel DP may be configured as a single panel. Alternatively, in embodiments, the display panel DP may be configured by connecting a plurality of panels.

The timing controller CON may generate a gate control signal GCTRL, a data control signal DCTRL, and an output image data ODAT based on a control signal CTRL and an input image data IDAT provided from an outside. For example, the control signal CTRL may include a vertical synchronization signal, a horizontal synchronization signal, an input data enable signal, a master clock signal, or the like. For example, the input image data IDAT may be RGB data including red image data, green image data, and blue image data. Alternatively, the input image data IDAT may include magenta image data, cyan image data, and yellow image data.

The gate driver GDV may generate gate signals based on the gate control signal GCTRL provided from the timing controller CON. For example, the gate control signal GCTRL may include a vertical start signal, a clock signal, or the like. In embodiments, the gate driver GDV may be manufactured as a separate panel and connected to the display panel DP. The gate driver GDV may be electrically connected to the display panel DP and sequentially output the gate signals. Each of the pixels P may receive a data signal according to control of each of the gate signals.

The data driver DDV may generate the data signal based on the data control signal DCTRL and the output image data ODAT provided from the timing controller CON. For example, the data control signal DCTRL may include an output data enable signal, a horizontal start signal, a load signal, or the like. In embodiments, the data driver DDV may be manufactured as a separate panel and may be electrically connected to the display panel DP. The data driver DDV may be electrically connected to the display panel DP and may generate a plurality of data signals. Each of the pixels P may display an image with a luminance corresponding to each of the data signals.

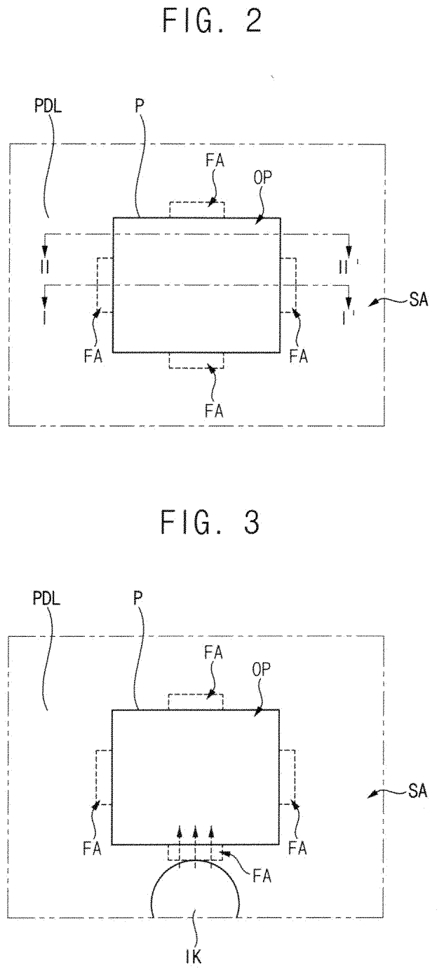

FIGS. 2 and 3 are plan views illustrating a pixel included in the display device of FIG. 1

Referring to FIG. 2, a pixel defining layer PDL may be disposed around the pixel P. The pixel P may be exposed through an opening OP of the pixel defining layer PDL. Although only one pixel P is illustrated in FIG. 2, a plurality of pixels P may be disposed in the display device. The plurality of pixels P may be partitioned from each other by the pixel defining layer PDL, and each of the pixels P may be exposed through different openings OP. Although the opening OP is illustrated as having a rectangular shape in FIG. 2, this is exemplary and the shape of the opening OP according to the invention is not limited thereto. For example, the opening OP may be a circle or a polygon other than a square in another embodiment.

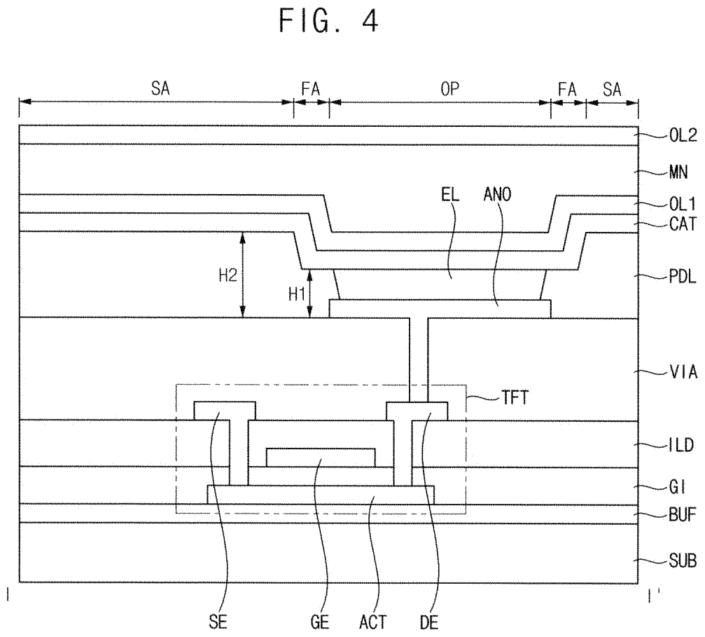

In embodiments, heights of the pixel defining layer PDL may be different for each location. A first height that is a height of a first region FA of the pixel defining layer PDL and a second height that is a height of a second region SA may be different from each other (See FIG. 4).

In an embodiment, for example, the second height may be higher than the first height. Accordingly, a step may be provided between the second region SA and the first region FA of the pixel defining layer PDL.

As illustrated in FIG. 3, ink IK may be applied on the pixel defining layer PDL and the pixel P. For example, the ink IK may be applied to form an organic encapsulation layer MN, which will be described later. The ink IK may be applied by an inkjet printing process. In this case, as the size of the pixels P becomes smaller and densely arranged, it may be difficult to accurately apply the ink IK to a desired position. Accordingly, the ink IK to be applied on the pixel P in order to protect the pixel P may be applied on the pixel defining layer PDL adjacent to the pixel P. Accordingly, the ink IK may not be disposed on the pixel P, and thus the pixel P may not be protected from external substances (moisture, dust, etc.) or impact.

However, in the pixel defining layer PDL according to embodiments, a step is formed between the second region SA and the first region FA, so that the ink applied to the pixel defining layer PDL may spread to the pixel P by capillary pressure Pc.

The capillary pressure Pc may be defined as the pressure generated at the interface between the gas surrounding the ink IK and the surface of the ink IK. The capillary pressure Pc may be defined as [Equation 1] as follows.

$$\begin{matrix}{P}_{c} = {P}_{non - wetting phase} - {P}_{wetting phase} \\ = {P}_{atr} - {P}_{water} \\ = γ ( \frac{1}{{R}_{x}} + \frac{1}{{R}_{y}} )\end{matrix} \qquad [ Equation 1 ]$$

Here, the Pnon-wetting phase and the Pair may be a pressure of the atmosphere around the ink INK, and the Pwetting phase and the Pwater may be a pressure of the surface of the ink INK. γ may be a surface tension, Rx is a length of the perimeter of the interface, Ry may be a depth of the interface.

As the capillary pressure Pc increases, the ink incorrectly applied on the pixel defining layer PDL may easily spread to the pixel P. To this end, as Rx is smaller in [Equation 1], the capillary pressure Pc may increase. In addition, as Ry in [Equation 1] is smaller, the capillary pressure Pc may increase.

Conventionally, only the second region SA exists, and accordingly, the second region SA may form an opening OP exposing the pixel P. However, in the pixel defining layer PDL according to embodiments, the first region FA may be separately provided at a position adjacent to the opening OP. In a plan view, a length of a perimeter of the first region FA is smaller than a length of a perimeter of the opening formed by the second region SA. That is, as a length of a perimeter of the first region FA decreases, the capillary pressure Pc applied to the ink IK applied on the second region SA adjacent to the first region FA may increase. Accordingly, the ink IK applied on the second region SA of the pixel defining layer PDL may easily spread to the opening OP by the capillary pressure Pc.

FIG. 4 is a cross-sectional view illustrating an embodiment of a cross-section taken along line I-I′ of FIG. 2.

Referring to FIGS. 2 and 4, a display device may include a substrate SUB, a buffer layer BUF, a transistor TFT, a gate insulating layer GI, an interlayer-insulating layer ILD, a via-insulating layer VIA, a pixel defining layer PDL, a light emitting element and encapsulation. The transistor TFT may include an active layer ACT, a gate electrode GE, a source electrode SE, and a drain electrode DE. The light emitting element may include a first electrode ANO, a light emitting layer EL, and a second electrode CAT. The encapsulation layer may include a first inorganic encapsulation layer OL1, an organic encapsulation layer MN, and a second inorganic encapsulation layer OL2.

The substrate SUB may be formed of or include a transparent or opaque material. Examples of the material that may be used as the substrate SUB may include glass, quartz, plastic, or the like. These may be used alone or in combination with each other. In embodiments, the substrate SUB may include polyimide. In this case, the substrate SUB may have a structure in which one or more polyimide layers and one or more barrier layers are alternately stacked.

The buffer layer BUF may be disposed on the substrate SUB. The buffer layer BUF may prevent diffusion of metal atoms or impurities from the substrate SUB to the transistor TFT. In embodiments, the buffer layer BUF may control a heat transfer rate during a crystallization process for forming the active layer ACT.

The active layer ACT may be disposed on the buffer layer BUF. In embodiments, the active layer ACT may be formed of or include a silicon semiconductor or an oxide semiconductor.

Examples of the material that may be used for the silicon semiconductor may include amorphous silicon, polycrystalline silicon, or the like. These may be used alone or in combination with each other.

Examples of materials that may be used as the oxide semiconductor may include zinc oxide (“ZnOx”), gallium oxide (“GaOx”), titanium oxide (“TiOx”), tin oxide (“SnOx”), indium oxide (“InOx”), indium-gallium oxide (“IGO”), Indium-zinc oxide (“IZO”), indium-tin oxide (“ITO”), gallium-zinc oxide (“GZO”), zinc-magnesium oxide (“ZMO”), zinc-tin oxide (“ZTO”), zinc-zirconium oxide (“ZnZrxOy”), indium-Gallium-zinc oxide (“IGZO”), indium-zinc-tin oxide (“IZTO”), indium-gallium-hafnium oxide (“IGHO”), tin-aluminum-zinc oxide (“TAZO”), indium-gallium-tin oxide (“IGTO”), etc. These may be used alone or in combination with each other.

The gate insulating layer GI may cover the active layer ACT and may be disposed on the buffer layer BUF. The gate insulating layer GI may be formed of or include an insulating material. For example, examples of the insulating material that may be used as the gate insulating layer GI may include silicon oxide (“SiOx”), silicon nitride (“SiNx”), silicon oxynitride (“SiON”), or the like. These may be used alone or in combination with each other.

The gate electrode GE may be disposed on the gate insulating layer GI. The gate electrode GE may be formed of or include a metal, an alloy, a conductive metal oxide, a transparent conductive material, or the like. For example, examples of materials that may be used as the gate electrode GE may include silver (“Ag”), an alloy containing silver, molybdenum (“Mo”), an alloy containing molybdenum, aluminum (“Al”), an alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide (“ITO”), indium zinc oxide (“IZO”), or the like. These may be used alone or in combination with each other.

The interlayer-insulating layer ILD may cover the gate electrode GE and may be disposed on the gate insulating layer GI. The interlayer-insulating layer ILD may be formed of or include an insulating material.

The source electrode SE and the drain electrode DE may be disposed on the interlayer-insulating layer ILD. The source electrode SE and the drain electrode DE may contact the active layer ACT. The source electrode SE and the drain electrode DE may be formed of or include a metal, an alloy, a conductive metal oxide, a transparent conductive material, or the like.

The via-insulating layer VIA may cover the source electrode SE and the drain electrode DE, and may be disposed on the interlayer-insulating layer ILD. The via-insulating layer VIA may be formed of or include an organic insulating material. For example, examples of the material that may be used as the via-insulating layer VIA may include photoresist, polyacrylic resin, polyimide resin, acrylic resin, or the like. These may be used alone or in combination with each other.

The first electrode ANO may be disposed on the via-insulating layer VIA. The first electrode ANO may be connected to the drain electrode DE through a contact hole defined by removing a portion of the via-insulating layer VIA. The first electrode ANO may be formed of or include a metal, an alloy, a conductive metal oxide, a transparent conductive material, or the like. In embodiments, the first electrode ANO may be an anode electrode.

The pixel defining layer PDL may be disposed on the via-insulating layer VIA to expose the first electrode ANO. The pixel defining layer PDL may define an opening OP exposing the first electrode ANO. The pixel defining layer PDL may be formed of or include an organic material. For example, examples of the material that may be used as the pixel defining layer PDL may include photoresist, polyacrylic resin, polyimide resin (particularly, photosensitive polyimide resin), acrylic resin, or the like. These may be used alone or in combination with each other.

The pixel defining layer PDL may have a different height for each region. For example, the pixel defining layer PDL may have a first height H1 in the first region FA and a second height H2 in the second region SA. The second region SA may be connected to the first region FA. In this case, the second height H2 may be higher than the first height H1. Accordingly, a step may be provided between the second region SA and the first region FA. In embodiments, a step may be provided in the pixel defining layer PDL by using a halftone mask when forming the pixel defining layer PDL.

Alternatively, in embodiments, when forming the pixel defining layer PDL, a lower pixel defining layer having a first height H1 is first formed, and an upper pixel defining layer having a third height that is the difference between the second height H2 and the first height may be additionally formed on the lower pixel defining layer. In this case, the lower pixel defining layer and the upper pixel defining layer may be made of the same material or different materials. The light emitting layer EL may be disposed on the first electrode ANO. The light emitting layer EL may contact the first electrode ANO in the opening OP. In embodiments, the light emitting layer EL may include an organic light emitting layer emitting red light, an organic light emitting layer emitting green light, or an organic light emitting layer emitting blue light. In addition, the light emitting layer EL may further include a hole injection layer, a hole transport layer, an electron injection layer, and an electron transport layer.

The second electrode CAT may be disposed on the light emitting layer EL. The second electrode CAT may be disposed to cover the light emitting layer EL and the pixel defining layer PDL. The second electrode CAT may be formed of or include a metal, an alloy, a conductive metal oxide, a transparent conductive material, or the like. In embodiments, the second electrode CAT may be a cathode electrode.

The encapsulation layer may be disposed on the second electrode CAT. Specifically, the first inorganic encapsulation layer OL1, the organic encapsulation layer MN, and the second inorganic encapsulation layer OL2 may be sequentially stacked. However, this is an example. In another embodiment, the encapsulation layer may have a structure in which a plurality of inorganic encapsulation layers and a plurality of organic encapsulation layers are stacked on each other.

The encapsulation layer may serve to prevent penetration of oxygen and/or moisture into the light emitting element. The first inorganic encapsulation layer IL1 and the second inorganic encapsulation layer IL2 may be formed of or include an inorganic material. The organic encapsulation layer MN may be formed of or include an organic material.

As described with reference to FIGS. 2 and 3, as the first region FA is separately formed, the ink IK applied to the second region SA may spread to the opening OP through the first region FA by the capillary pressure Pc.

In embodiments, the first height H1 may be about 0.1 micrometers to about 1.9 micrometers. When the first height H1 is less than 0.1 micrometers, light emitted from the light emitting device is not blocked by the pixel defining layer PDL, so that the pixel defining layer PDL may not sufficiently partition a boundary between the light emitting elements. Accordingly, the first height H1 is preferably not lowered by about 0.1 micrometers.

Also, when the first height H1 is higher than 1.9 micrometers, the step between the first region FA and the second region SA may not be properly formed. Accordingly, the capillary pressure Pc acting on the ink applied to the second region SA may be lowered, and thus the ink may not sufficiently spread to the opening OP.

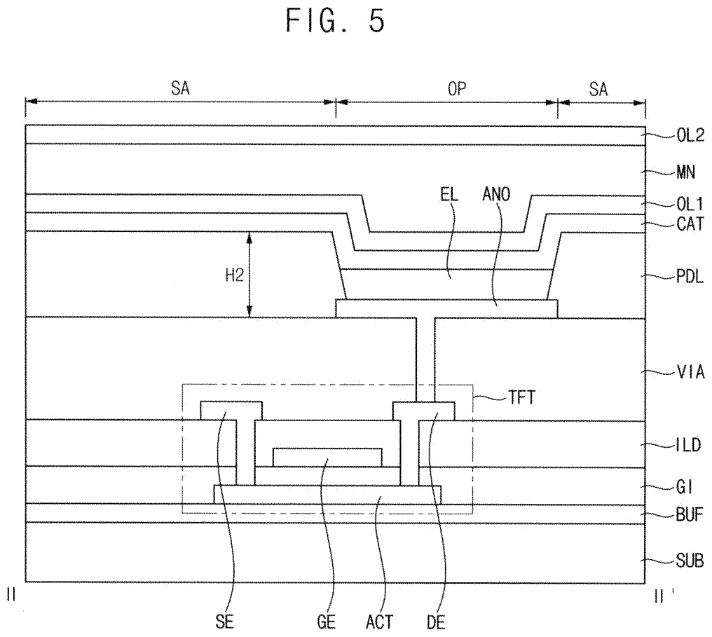

FIG. 5 is a cross-sectional view illustrating an embodiment of a cross-section taken along line II-II′ of FIG. 2. FIG. 5 may be substantially the same as FIG. 4, except that a step is not formed in the pixel defining layer PDL. Accordingly, a description of the overlapping configuration will be omitted.

Referring to FIGS. 2 and 5, the second region SA may define the opening OP. The first region FA may be disposed only partially along the perimeter of the opening OP. Accordingly, in the region where the first region FA is provided, the second region SA may be spaced apart from the opening OP by the first region FA. The pixel defining layer PDL may be provided without forming a step in the periphery of the opening OP in which the first region FA is not disposed.

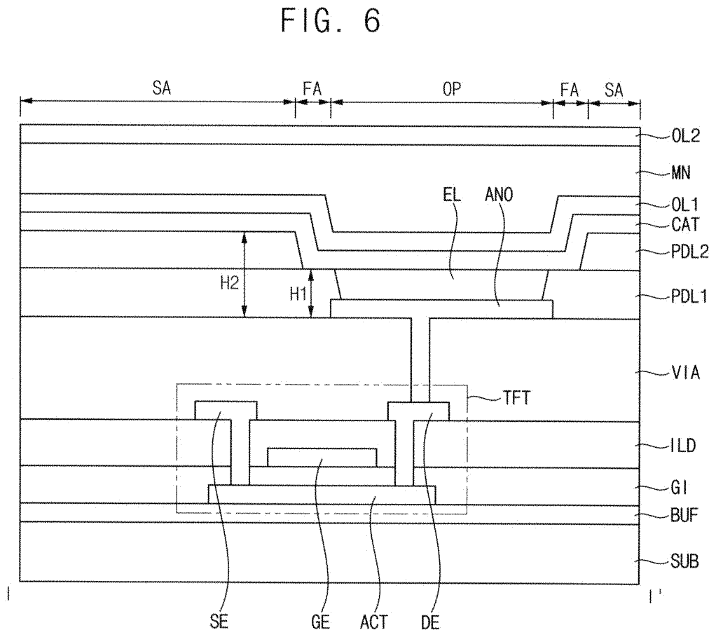

FIG. 6 is a cross-sectional view illustrating another embodiment of a cross-section taken along line I-I′ of FIG. 2. FIG. 6 may be substantially the same as FIG. 4, except that the pixel defining layer is divided into a lower pixel defining layer PDL1 and an upper pixel defining layer PDL2. Accordingly, a description of the overlapping configuration will be omitted.

Referring to FIG. 6, a lower pixel defining layer PDL1 having a first height H1 may be disposed on the via-insulating layer VIA to have an opening exposing the first electrode ANO. Thereafter, the upper pixel defining layer PDL2 may be disposed on the lower pixel defining layer PDL1. In this case, the height of the upper pixel defining layer PDL2 may be a height excluding the first height H1 from the second height H2.

In embodiments, the lower pixel defining layer PDL1 and the upper pixel defining layer PDL2 may include the same material. Alternatively, in embodiments, the lower pixel defining layer PDL1 and the upper pixel defining layer PDL2 may include different materials.

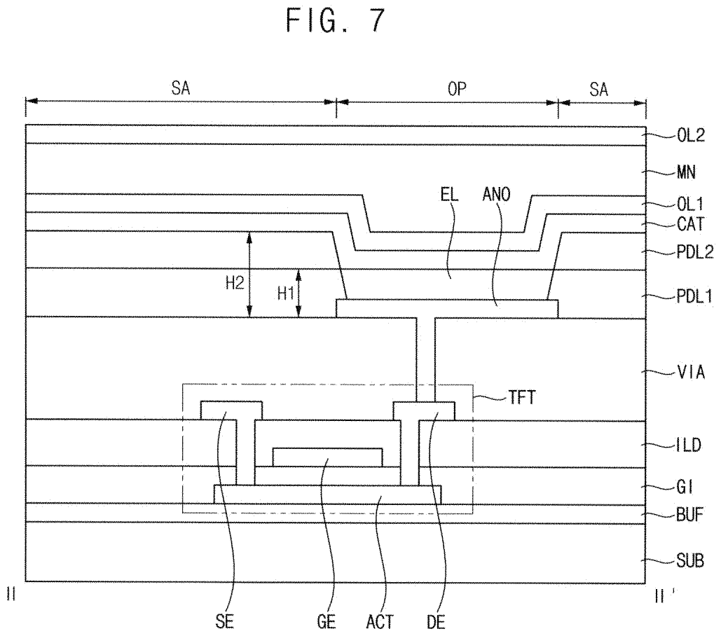

FIG. 7 is a cross-sectional view illustrating an embodiment of a cross-section taken along line II-II′ of FIG. 2. FIG. 7 may be substantially the same as FIG. 5 except that the pixel defining layer includes a lower pixel defining layer PDL1 and an upper pixel defining layer PDL2. Accordingly, a description of the overlapping configuration will be omitted.

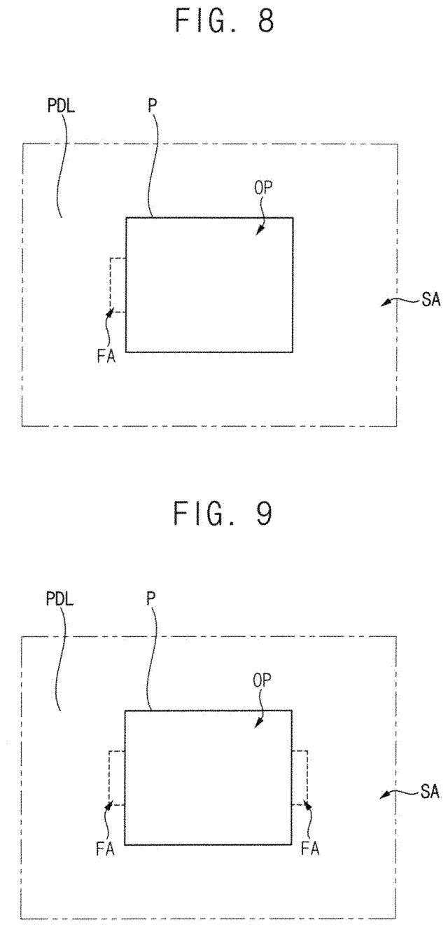

FIGS. 8, 9, 10, and 11 are plan views illustrating other embodiments of pixels included in the display device of FIG. 1.

Referring to FIG. 8, the first region FA may be provided on only one side surface of the pixel defining layer PDL that partitions the pixel P. That is, the pixel defining layer PDL may be formed with a step difference only on one side of the pixel P.

Referring to FIG. 9, the first region FA may be provided on opposite sides of the pixel defining layer PDL that partitions the pixel P. That is, the pixel defining layer PDL may be provided to have a step difference at both sides of the pixel P.

In addition, the first region FA may be provided on three side surfaces of the pixel defining layer PDL that partitions the pixel P. In addition, two or more first regions FA may be provided on at least one side surface.

As the number of the first region FA having a shorter perimeter increases, the ink IK may be strongly subjected to capillary pressure in the direction of the first region FA applied to the second region SA. Accordingly, it may be desirable to form more first regions FA having a shorter perimeter on each side surface of the pixel defining layer PDL that partitions the pixel P.

Also, in embodiments, regions having different perimeter lengths and a step difference may be provided on each side surface of the pixel defining layer PDL that partitions the pixel P.

Referring to FIG. 10, the pixel P may have a circular shape. The pixel defining layer PDL may define a circular opening. Also in this case, a plurality of first regions FA may be provided along the perimeter of the pixel defining layer PDL that partitions the pixel P. Although four first regions FA are illustrated in FIG. 10, this is exemplary and the number of the first regions FA according to the invention is not limited thereto. For example, the first regions FA may be provided in the pixel defining layer PDL to be spaced apart from each other by an interval of 120 degrees in another embodiment.

In addition, although it is illustrated in FIG. 10 that the first regions FA having the same perimeter length are provided, this is exemplary and regions having different perimeter lengths have a step difference and may be provided along the opening OP.

Referring to FIG. 11, the pixel P may have a hexagonal opening OP. In addition to this, the pixel P may have not only a hexagonal shape or a rectangular shape, but also an N-gonal opening (where N is a natural number equal to or greater than 3).

Also, the first region FA may be provided not only as a rectangle but also as a triangle. In addition, the first region FA may have an M-shaped or circular shape (provided that M is a natural number equal to or greater than 3).

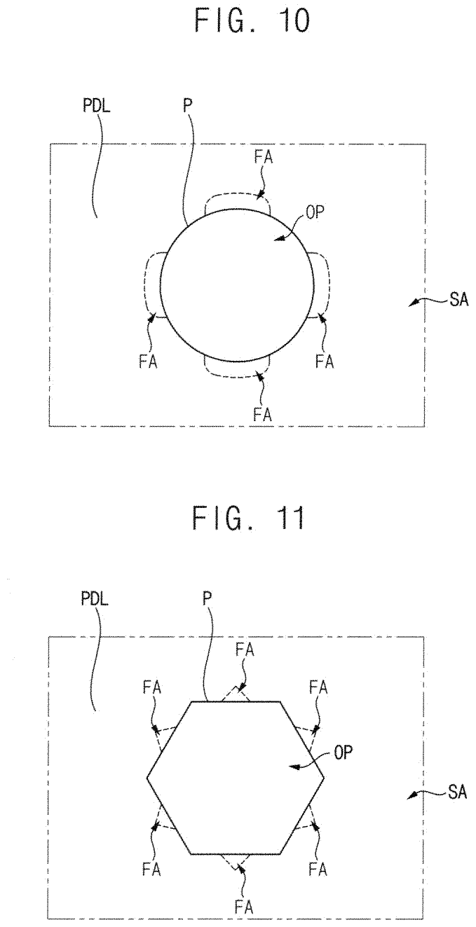

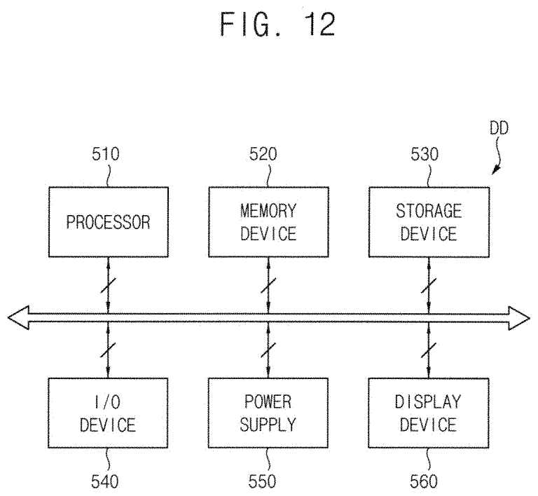

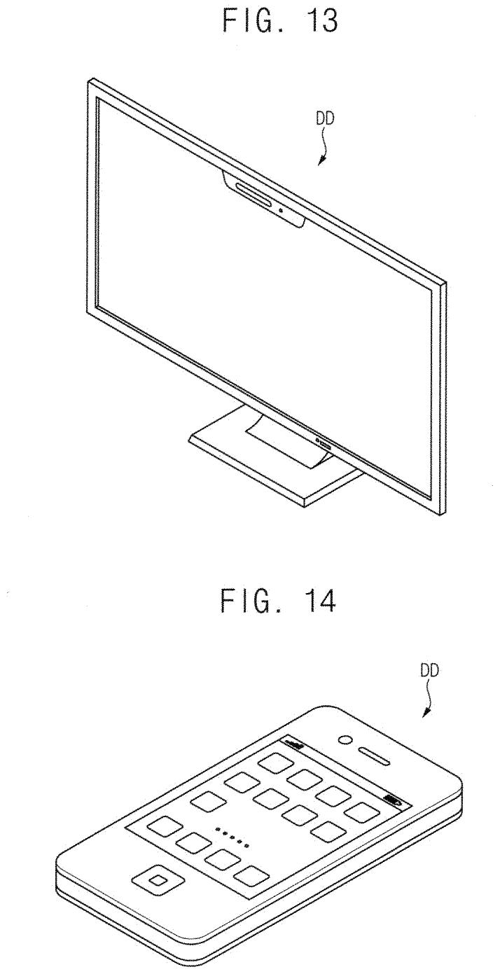

FIG. 12 is a block view illustrating an electronic device according to an embodiment, FIG. 13 is a view an example in which the electronic device of FIG. 12 is implemented as a television, and FIG. 14 is a view illustrating an example in which the electronic device of FIG. 12 is implemented as a smartphone.

Referring to FIGS. 12, 13 and 14, an electronic device DD may include a processor 510, a memory device 520, a storage device 530, an input/output device 540, a power supply 550, and a display device 560. In this case, the display device 560 may correspond to the display device described with reference to the aforementioned drawings. The electronic device DD may further include several ports capable of communicating with a video card, a sound card, a memory card, a USB device, or the like. In an embodiment, as illustrated in FIG. 13, the electronic device DD may be implemented as a television. In another embodiment, as illustrated in FIG. 14, the electronic device DD may be implemented as a smartphone. However, the electronic device DD according to the invention is not limited thereto, and for example, the electronic device DD includes a mobile phone, a video phone, a smart pad, a smart watch, a tablet PC, a vehicle navigation system, It may be implemented as a computer monitor, notebook computer, head mounted display (“HMD”), or the like.

The processor 510 may perform specific calculations or tasks. In an embodiment, the processor 510 may be a micro processor, a central processing unit (“CPU”), an application processor (“AP”), or the like. The processor 510 may be connected to other components through an address bus, a control bus, a data bus, or the like. In an embodiment, the processor 510 may also be connected to an expansion bus such as a peripheral component interconnect (“PCI”) bus.

The memory device 520 may store data necessary for the operation of the electronic device DD. For example, the memory device 520 may include nonvolatile memory device such as an erasable programmable read-only memory (“EPROM”) device, an electrically erasable programmable read-only memory (“EEPROM”) device, a flash memory device, and a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and/or volatile memory device such as a dynamic random access memory (“DRAM”) device, a static random access memory (“SRAM”) device, a mobile DRAM device.

The storage device 530 may include a solid state drive (“SSD”), a hard disk drive (“HDD”), a CD-ROM, or the like. The input/output device 540 may include an input means such as a keyboard, a keypad, a touch pad, a touch screen, and a mouse, and an output means such as a speaker and a printer.

The display device according to the embodiments may be applied to a display device included in a computer, a notebook, a mobile phone, a smartphone, a smart pad, a PMP, a PDA, an MP3 player, or the like.

Although the display devices according to the embodiments have been described with reference to the drawings, the illustrated embodiments are examples, and may be modified and changed by a person having ordinary knowledge in the relevant technical field without departing from the technical spirit of the disclosure. Accordingly, the scope of the disclosure should not be limited by the disclosed embodiments, but rather should be interpreted in accordance with the following claims including their equivalents.

What is claimed is:

1. A display device, comprising:
a substrate;
a first electrode disposed on the substrate; and
a pixel defining layer disposed on the substrate and which exposes the first electrode and includes a first region having a first height and a second region connected to the first region and having a second height higher than the first height.

2. The display device of claim 1, further comprising:
a light emitting layer disposed on the first electrode;
a second electrode disposed on the light emitting layer; and
an encapsulation layer disposed on the second electrode.

3. The display device of claim 2, wherein the encapsulation layer includes:
a first inorganic encapsulation layer disposed on the second electrode;
an organic encapsulation layer disposed on the first inorganic encapsulation layer; and
a second inorganic encapsulation layer disposed on the organic encapsulation layer, and
wherein the organic encapsulation layer is formed by an inkjet printing process, and is spread from the second region to the first region by capillary pressure.

4. The display device of claim 1, wherein the first height is in a range of about 0.1 micrometers to about 1.9 micrometers.

5. The display device of claim 1, wherein, in a plan view, a region in which the pixel defining layer exposes the first electrode has a circular shape.

6. The display device of claim 5, wherein the first region is provided in plural, and the plurality of first regions are disposed along a perimeter of the circular shape and are spaced apart from each other.

7. The display device of claim 6, wherein a length of a perimeter of a first one of the plurality of first regions is different from a length of a perimeter of a second one of the plurality of first regions.

8. The display device of claim 6, wherein the second region is disposed adjacent to the first electrode, and a portion of the second region is spaced apart from the first electrode by the first region.

9. The display device of claim 1, wherein, in a plan view, a region in which the pixel defining layer exposes the first electrode has a polygonal shape.

10. The display device of claim 9, wherein the first region is provided in plural, and the plurality of first regions are disposed along a perimeter of the polygonal shape and are spaced apart from each other.

11. The display device of claim 10, wherein a length of a perimeter of a first one of the plurality of first regions is different from a length of a perimeter of a second one of the plurality of first regions.

12. The display device of claim 10, wherein the second region is disposed adjacent to the first electrode, and a portion of the second region is spaced apart from the first electrode by the first region.

13. The display device of claim 1, wherein the pixel defining layer includes:
a lower pixel defining layer having the first height; and
an upper pixel defining layer disposed on the lower pixel defining layer and having a third height that is a difference between the second height and the first height.

14. The display device of claim 13, wherein the lower pixel defining layer and the upper pixel defining layer include a same material.

15. The display device of claim 13, wherein the lower pixel defining layer and the upper pixel defining layer include different materials from each other.

16. The display device of claim 1, wherein, in a plan view, a length of a perimeter of a region in which the pixel defining layer exposes the first electrode is longer than a length of a perimeter of the first region.

17. The display device of claim 1, wherein, in a plan view, the first region has a circular shape.

18. The display device of claim 1, wherein, in a plan view, the first region has a polygonal shape.
